(19) United States
(12) Patent Application Publication
(10) Pub. No.: US 2007/0166881 A1
(43) Pub. Date: Jul. 19, 2007

(54) PACKAGE STRUCTURE AND METHOD FOR MANUFACTURING THE SAME

(75) Inventor: Chien LIU, Kaohsiung City (TW)

Correspondence Address: LOWE HAUPTMAN BERNER, LLP, 1700 DIAGONAL ROAD, SUITE 300, ALEXANDRIA, VA, 22314, US

(73) Assignee: ADVANCED SEMICONDUCTOR ENGINEERING, INC., Kaohsiung (TW)

(21) Appl. No.: 11/609,856

(22) Filed: Dec. 12, 2006

(30) Foreign Application Priority Data
Dec. 30, 2005 (TW) 094147707

(51) Int. Cl. H01L 23/48; H01L 21/00

(52) U.S. Cl. 438/108; 257/778

(57) ABSTRACT

In the present invention, a package structure and the method for manufacturing the same are provided. The package structure includes a substrate and a chip flip-chip bonded to the substrate. The chip has central connecting pads and surrounding connecting pads surrounding the central connecting pads. A plurality of first bumps and second bumps are disposed on the central connecting pads and surrounding connecting pads respectively in order to electrically connect the chip and substrate. The second bumps have indentations that can increase the areas to be soldered thereby balancing the bonding force of the solder to bond the second bumps to the corresponding contact pads of a substrate to avoid the detachment of the second bumps from the contact pads.

### CROSS REFERENCE TO RELATED APPLICATION

This application claims the priority benefit of Taiwan Patent Application Serial Number 094147707 filed Dec. 30, 2005, the full disclosure of which is incorporated herein by reference.

### BACKGROUND OF THE INVENTION

1. Field of the Invention

The present invention relates to a package structure and the method for manufacturing the same, and more particularly, to a package structure that can prevent bumps from detaching from a chip and the method for manufacturing the same.

2. Description of the Related Art

As chip designs get more and more complex and I/O density increases significantly, conventional wire-bonding techniques have been inappropriate for manufacturing such chips because the bonding wires are closely spaced and therefore apt to contact with each other to cause a shot circuit. Accordingly, the flip-chip package technology has been developed to solve this problem. The flip-chip package technology is to form metal conductor instead of bonding wires on the active surface of a chip to electrically connect with the traces in the chip. The chip is bonded to and electrically connected to a substrate by the metal conductors in a face down fashion. It is not required for the flip-chip package technology to reserve a room for the bonding wires. Therefore, the flip-chip package technology is becoming more popular to package a chip with high I/O counts. The flip-chip package technology has also the advantages of being able to form a package that has a low signal delay, a smaller chip carrier and less production cost. The metal conductors for flip-chip package can be metal bumps or high-lead bumps.

However, the contact pads disposed on a substrate for flip-chip package will have a slight shift toward the edge of the substrate since the substrate expands during manufacture. Referring to FIG. 1a, a contact pad 12 is disposed on the center of a substrate 10. Contact pads 14, 16 are disposed on the substrate 10 and around the central contact pad 12. The contact pads 14, 16 have slightly shifted away from their predetermined positions toward the edge of the substrate 10. The contact pads 16 farther from the central contact pad 12 than the contact pads 14 have more shift than the contact pads 14 have.

Referring to FIG. 1b, when a chip 20 is flip-chip bonded to the substrate 10, only the metal bump 27 disposed on the central connecting pad 22 of the chip 20 can precisely align with the central contact pad 12 on the substrate 10. The solder 18 to bond the metal bump 27 to the contact pad 12 can therefore be equally distributed over two opposite sides of the metal bump 27. However, the metal bumps 28, 29 disposed respectively on the connecting pads 24, 26 of the chip 20 cannot precisely align with the contact pads 14, 16 respectively as a result of the shift of the contact pads 14, 16. This will cause the sides of the metal bumps 28, 29 farther from the metal bump 27 to be attached more solder 18 than the opposite sides closer to the metal bump 27. This effect will become more pronounced as the metal bump is much farther from the metal bump 27. This is because the farther the metal bump is from the metal bump 27, the more shift the metal bump will have.

Therefore, unequal distribution of the solder 18 over the two opposite sides of the metal bumps 28, 29 will cause the bonding force of the solder 18 to bond the metal bumps 28, 29 to the corresponding contact pads 14, 16 to be unequal between the two opposite sides. Although a ball limiting metallurgy (BLM) 30 is used to help to bond the metal bumps 27, 28, 29 to the connecting pads 22, 24, 26 on the chip 20 respectively, the metal bumps 28, 29 are still potential to detach from the contact pads 14, 16 as a result of the unequal bonding force between the two opposite sides.

The detachment of the metal bumps 28, 29 from the contact pads 14, 16 will result in an open circuit between the chip 20 and substrate 10 and the yield of the package structure will be lowered accordingly.

Accordingly, there exists a need to provide a package structure and method for manufacturing the same to solve the aforesaid problems.

### SUMMARY OF THE INVENTION

It is an object of the present invention to provide a chip structure that can avoid the detachment of the bumps of the chip from the contact pads of a substrate as a result of the shift of the contact pads toward the edge of the substrate when the chip is flip-chip bonded to the substrate.

It is another object of the present invention to provide a package structure that can make two opposite sides of the surrounding bumps of a chip have equal areas to be soldered thereby balancing the bonding force of the solder to bond the bumps to the corresponding contact pads of a substrate to avoid the detachment of the bumps from the contact pads.

It is a further object of the present invention to provide a method for manufacturing the package structure of the present invention.

In order to achieve the above objects, the package structure of the present invention includes a chip having opposing active and back surfaces and a substrate having a plurality of contact pads. A plurality of central connecting pads and surrounding connecting pads are disposed on the central region and the surrounding region of the active surface respectively. A ball limiting metallurgy is disposed on the central connecting pads and surrounding connecting pads. A plurality of first bumps and second bumps are disposed on the ball limiting metallurgy of the central connecting pads and surrounding connecting pads respectively. Each of the second bumps has a first portion and a second portion divided by the central line of the second bump. The first portion is different from the second portion in shape. The first bumps and second bumps are bonded to the contact pads by soldering.

The method for manufacturing the package structure of the present invention is to utilize two masks at two stages to respectively form the first bumps and second bumps. Each of the resulting second bumps has a first portion and a second portion different from the first portion in shape or size. The different first and second portions can make two opposite sides of the second bumps have equal areas to be soldered thereby balancing the bonding force of the solder to bond the second bumps to the corresponding contact pads of a substrate to avoid the detachment of the second bumps from the contact pads.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1a is a cross-sectional view of a conventional substrate.

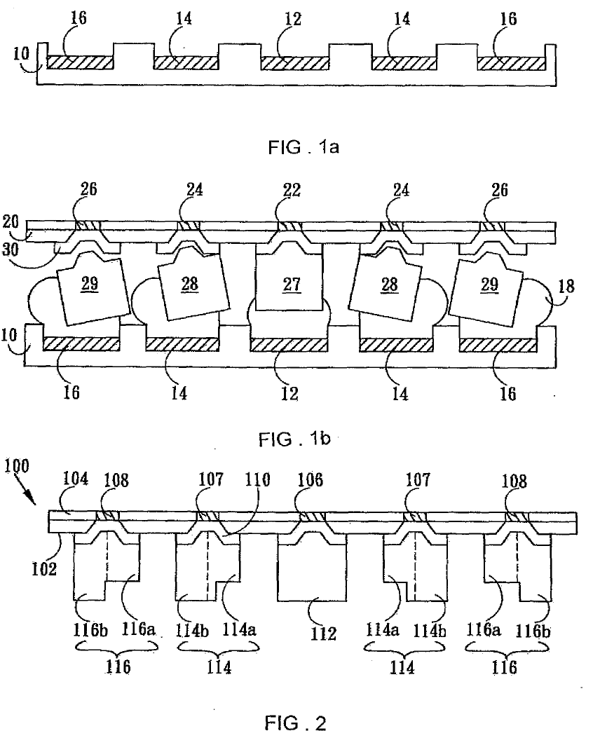

FIG. 1b is a cross-sectional view of a conventional package structure.

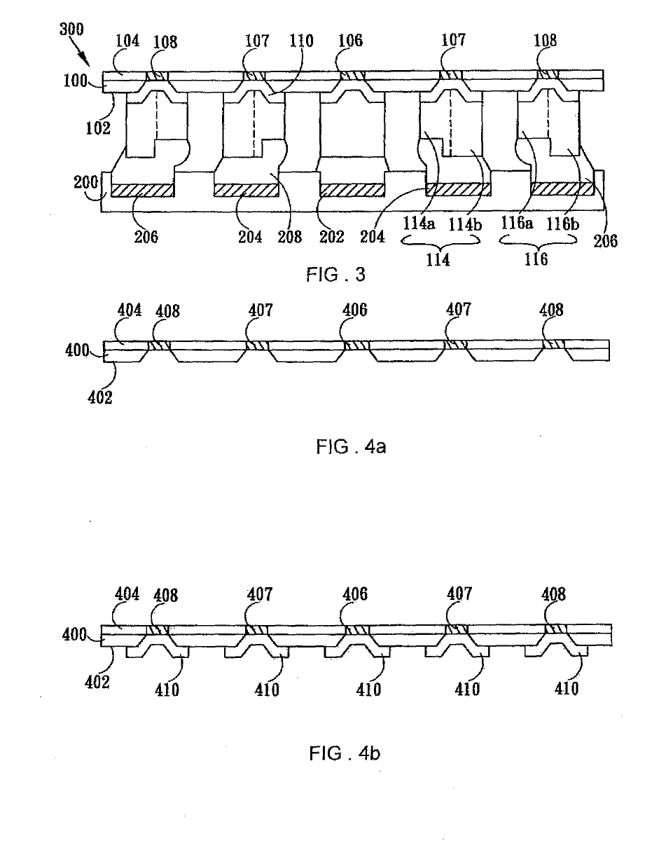

FIG. 2 is a cross-sectional view of a chip structure according to an embodiment of the present invention.

FIG. 3 is a cross-sectional view of a package structure according to another embodiment of the present invention.

FIGS. 4a to 4i illustrate a method for manufacturing the package structure according to an embodiment of the present invention.

FIGS. 5a to 5c illustrate a method for manufacturing the package structure according to another embodiment of the present invention.

### DETAILED DESCRIPTION OF THE PREFERRED EMBODIMENT

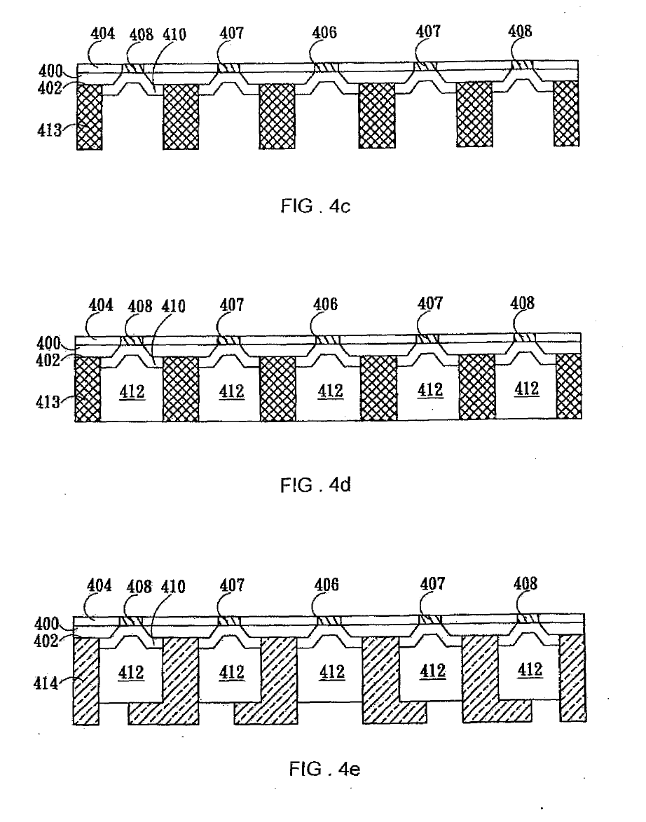

Referring to FIG. 2, it illustrates a chip structure 100 according to an embodiment of the present invention. The chip 100 includes opposing active and back surfaces 102, 104, at least one central connecting pad 106 disposed on the central region of the active surface 102 and a plurality of surrounding connecting pads 107, 108 disposed on the surrounding region of the active surface 102 and around the central connecting pad 106. A ball limiting metallurgy 110 is formed on the connecting pads 106, 107, 108. A first bump 112 is disposed on the ball limiting metallurgy 110 of the central connecting pad 106. A plurality of second bumps 114 and 116 is disposed on the ball limiting metallurgy 110 of the surrounding connecting pads 107 and 108 respectively. The second bump 114 includes a first portion 114a and a second portion 114b. The second bump 116 includes a first portion 116a and a second portion 116b. The first portions 114a, 116a are different from the second portions 114b, 116b in shape or size.

In this embodiment, the second bumps 114, 116 are step-shaped. The first portions 114a, 116a have indentations, and each of the indentations faces the first bump 112. The indentations on the second bumps 116 are larger than the indentations on the second bumps 114. In other words, the first portions 116a of the second bumps 116 farther from the first bump 112 will have larger surfaces to be soldered than the first portions 114a of the second bumps 114 closer to the first bump 112 have. These indentations can make two opposite sides of the second bumps 114, 116 have equal areas to be soldered and therefore compensate for the shift of the contact pads on the conventional substrate as previously described. This will make the bonding force of the solder to bond the second bumps 114, 116 to the corresponding contact pads balanced. In addition, the bumps 112, 114, 116 can be copper bumps or high-lead bumps.

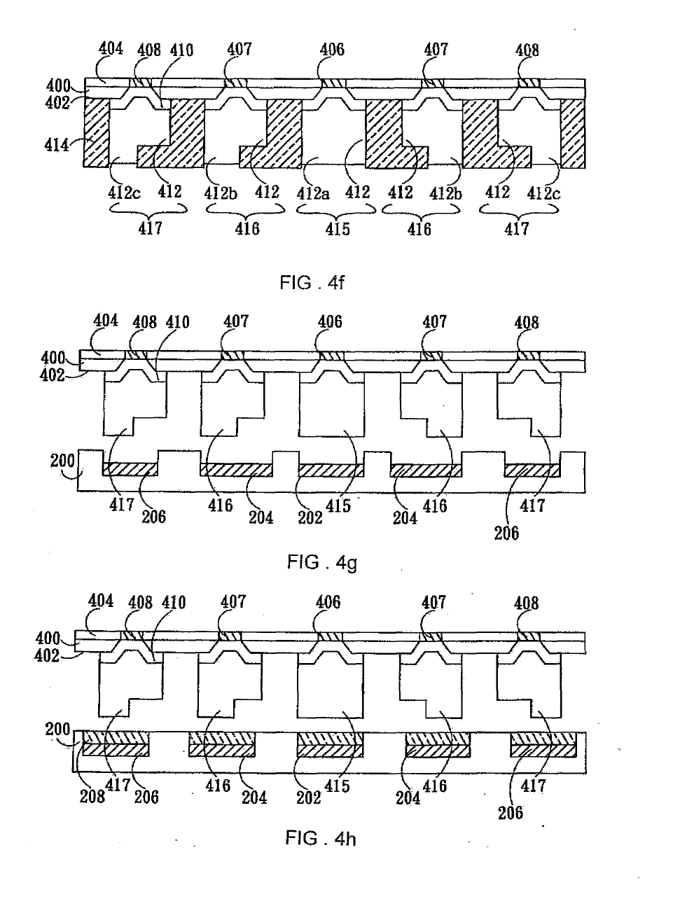

Referring to FIG. 3, it illustrates a package structure 300 according to another embodiment of the present invention. The package structure 300 includes a substrate 200 attached with the chip 100. The chip 100 is the same as the chip of FIG. 2. Thus, any further illustration of the chip 100 will be omitted herein. The substrate 200 is provided with a plurality of contact pads 202, 204, 206 thereon for bonding to the chip 100. As described above, the substrate 200 is apt to expand during manufacture. The surrounding contact pads 204, 206 on the substrate 200 will therefore have a slight shift toward the edge of the substrate 200. This will cause the second bumps 114, 116 of the chip 100 not to precisely align with the surrounding contact pads 204, 206 when the chip 100 is flip-chip bonded to the substrate 200. The first bump 112 and second bumps 114, 116 are respectively bonded to contact pads 202, 204, 206 on the substrate 200 by solder 208. Since the first portions 114a, 116a of the second bumps 114, 116 have the indentations, the areas on the first portions 114a, 116a for the solder 208 to bond will therefore increase and be equal to the areas on the second portions 114b, 116b for the solder 208 to bond. This will solve the problem in the prior art as previously described. The detachment of the bumps from the contact pads can be avoided.

Furthermore, in this embodiment, an underfill (not shown in the figure) can be used to fill up the area between the chip 100 and substrate 200 to protect the electrical connection therein. In addition, the bumps 112, 114, 116 can be copper bumps or high-lead bumps.

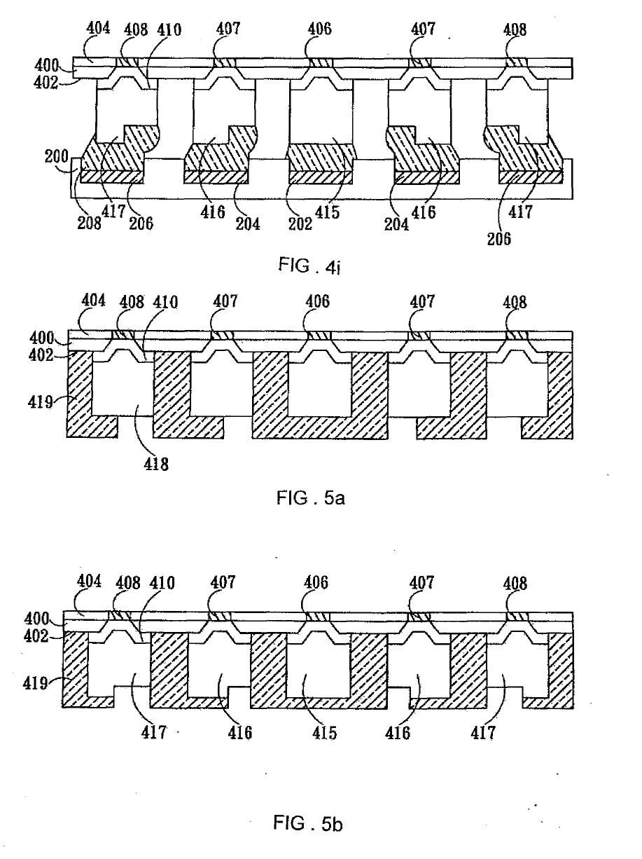

Referring to FIGS. 4a to 4i, they illustrate a method for manufacturing the package structure according to an embodiment of the present invention. Referring to FIG. 4a, a chip 400 is first provided. The chip 400 has opposing active and back surfaces 402, 404, at least one central connecting pad 406 disposed on the central region of the active surface 402 and a plurality of surrounding connecting pads 407, 408 disposed on the surrounding region of the active surface 402 and around the central connecting pad 406. Second, referring to FIG. 4b, a ball limiting metallurgy (BLM) 410 is formed on the connecting pads 406, 407, 408. The BLM 410 is used to help to bond metal bumps to the connecting pads 406, 407, 408 and restrict these metal bumps.

Referring to FIG. 4c, a first mask 413 is formed on the active surface 402 of the chip 400 and exposes the connecting pads 406, 407, 408. The first mask 413 can be made of a photoresist or a metal. Referring to FIG. 4d, a plurality of bottom bumps 412 is then formed on the connecting pads 406, 407, 408. The bottom bumps 412 can be copper bumps or high-lead bumps and formed by evaporation, plating or printing.

Referring to FIG. 4e, after the first mask 413 is removed, a second mask 414 is formed on the bottom bumps 412. The second mask 414 exposes the entire bottom bump 412 on the central connecting pad 406 and portions of the bottom bumps 412 on the surrounding connecting pads 407, 408. Likewise, the second mask 414 can made of a photoresist or a metal. In addition, the areas on the bottom bumps 412 of the surrounding connecting pads 407 covered by the second mask 414 are smaller than the areas on the bottom bumps 412 of the surrounding connecting pads 408 covered by the second mask 414. That is to say, the exposed areas on the bottom bumps 412 of the surrounding connecting pads 407 closer to the central connecting pad 406 are larger than the exposed areas on the bottom bumps 412 of the surrounding connecting pads 408 farther from the central connecting pad 406.

Referring to 4f, the exposed area on the bottom bump 412 of the central connecting pad 406 is formed a top bump 412a and the exposed areas on the bottom bumps 412 of the surrounding connecting pads 407 and 408 are formed a plurality of top bumps 412b and 412c respectively. The top bumps 412a, 412b, 412c can be copper bumps or high-lead bumps and formed by evaporation, plating or printing. The size of the top bump decreases with the increase in distance from the center of the chip 400. In other words, as shown in the figure, the top bump 412a on the central connecting pad 406 is largest and the top bumps 412c on the surrounding pad 408 are smallest. The combination of the top bump 412a and the bottom bump 412 on the central connecting pad 406 forms a first bump 415. The combinations of the top bumps 412b and the bottom bump 412 on the surrounding connecting pads 407 form a plurality of second bumps 416 and the combinations of the top bumps 412c and the bottom bump 412 on the surrounding connecting pads 408 form a plurality of second bumps 417.

Referring to FIG. 4g, after the second mask 414 is removed, a substrate 200 is prepared to align with the chip 400 for flip-chip bonding to the chip 400. The substrate 200 has a plurality of contact pads 202, 204, 206 thereon for flip-chip bonding to the chip 400. As described above, the substrate 200 is apt to expand during manufacture. The surrounding contact pads 204, 206 on the substrate 200 will therefore have a slight shift toward the edge of the substrate 200. This will cause the second bumps 416, 417 of the chip 400 not to precisely align with the surrounding contact pads 204, 206 when the chip 400 is flip-chip bonded to the substrate 200. Only the first bump 415 on the central connecting pad 406 can precisely align with the central contact pad 202.

Referring to FIG. 4h, a layer of solder 208 is formed on the contact pads 202, 204, 206 by coating, application, or printing. Referring to FIG. 4i, the chip 400 is flip-chip bonded to and electrically connected to the substrate 200 by soldering the first bump 415, second bumps 416 and 417 respectively to the central contact pad 202, surrounding contact pads 204 and 206 with the solder 208. The second bumps 416, 417 of the chip 400 have indentations. As described above, these indentations can make two opposite sides of the second bumps 416, 417 have equal areas to be soldered by the solder 208. This will make the bonding force of the solder 208 to bond the second bumps 416, 417 to the corresponding contact pads 204, 206 balanced. Accordingly, the detachment of the bumps from the contact pads can be avoided. In addition, in this embodiment, an underfill (not shown in the figure) can be used to fill up the area between the chip 400 and substrate 200 to protect the electrical connection therein.

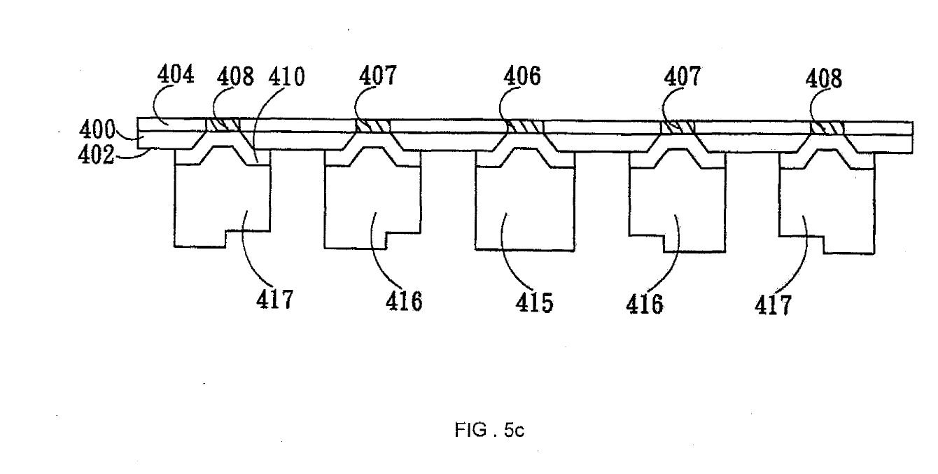

According to the method for manufacturing the package structure of another embodiment of the present invention, different steps are adopted to form the first and second bumps. The detailed description about these steps will be provided in the following paragraphs with reference to FIGS. 5a to 5c.

Referring to FIG. 5a, after a first mask 413 is used to form a plurality of bumps 418 on the connecting pads 406, 407, 408, the first mask 413 is removed. A third mask 419 is then formed on the active surface 402 of the chip 400 and the bumps 418. The third mask 419 covers the entire bump 418 on the central connecting pad 406 and portions of the bumps 418 on the surrounding connecting pads 407, 408. In addition, the areas on the bumps 418 of the surrounding connecting pads 407 covered by the third mask 419 are larger than the areas on the bumps 418 of the surrounding connecting pads 408 covered by the third mask 419.

Referring to FIG. 5b, portions of the thickness of the exposed areas on the bumps 418 of the surrounding connecting pads 407, 408 are removed by etching or otherwise to respectively form step-shaped second bumps 416, 417 with indentations. Since the bump 418 on the central connecting pad 406 is completely covered by the third mask 419, the resulting first bump 415 keeps unchanged and therefore has no indentation. In addition, the indentations on the second bumps 416 are smaller than the indentations on the second bumps 417 since the areas on the bumps 418 of the surrounding connecting pads 407 covered by the third mask 419 are smaller than the areas on the bumps 418 of the surrounding connecting pads 408 covered by the third mask 419.

Referring to FIG. 5c, the third mask 419 is removed and the chip 400 with the first bump 415 and second bumps 416, 417 is formed. The package structure according to the present invention can be then formed with following the steps as shown in FIGS. 4g to 4i.

In the above embodiments, a chip is provided with only one central connecting pad in the accompanying drawings for clarity. However, it should be understood that a chip can be provided with a plurality of central connecting pads thereon.

According to the embodiments of present invention, the indentations formed on the bumps on the surrounding connecting pads of the chip can make two opposite sides of the bumps have equal areas to be soldered and therefore compensate for the shift of the contact pads toward the edge of the substrate as a result of the expansion of the substrate. This will make the bonding force of the solder to bond the bumps to the corresponding contact pads balanced. The detachment of the bumps from the corresponding contact pads as a result of the unbalanced bonding force can therefore be avoided.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A chip structure, comprising:
opposing active and back surfaces;
a plurality of central connecting pads disposed on a central region of the active surface;
a plurality of surrounding connecting pads disposed on a surrounding region of the active surface and around the central connecting pads;
a plurality of first bumps disposed on the central connecting pads; and
a plurality of second bumps disposed on the surrounding connecting pads, each of the second bumps having a first portion and a second portion divided by a central line of the second bump, wherein the first portion is different from the second portion in shape or size.

2. The chip structure as claimed in claim 1, further comprising:
a ball limiting metallurgy formed on the central and surrounding connecting pads.

3. The chip structure as claimed in claim 1, wherein the second bump is step-shaped.

4. The chip structure as claimed in claim 1, wherein the first portion of the second bump has an indentation.

5. The chip structure as claimed in claim 1, wherein the indentation of the second bump faces the first bump.

6. The chip structure as claimed in claim 1, wherein the indentation of the second bump changes a size with a different distance from the center of the chip.

7. The chip structure as claimed in claim 6, wherein the farther the second bump is from the center of the chip, the larger the indentation of the second bump is.

8. The chip structure as claimed in claim 4, wherein the first portion of the second bump is closer to the center of the chip than the second portion is.

9. A package structure, comprising:
a chip having opposing active and back surfaces, a plurality of central connecting pads disposed on a central region of the active surface and a plurality of surrounding connecting pads disposed on a surrounding region of the active surface and around the central connecting pads;
a ball limiting metallurgy disposed on the central connecting pads and surrounding connecting pads;
a plurality of first bumps disposed on the ball limiting metallurgy of the central connecting pads;
a plurality of second bumps disposed on the ball limiting metallurgy of the surrounding connecting pads, each of the second bumps having a first portion and a second portion divided by a central line of the second bump, wherein the first portion is different from the second portion in shape or size; and
a substrate having a plurality of contact pads, wherein the first bumps and second bumps are bonded to the contact pads by soldering.

10. The package structure as claimed in claim 9, wherein the second bump is step-shaped.

11. The package structure as claimed in claim 9, wherein the first portion of the second bump has an indentation.

12. The package structure as claimed in claim 9 wherein the indentation of the second bump faces the first bump.

13. The package structure as claimed in claim 9, wherein the indentation of the second bump changes a size with a different distance from the center of the chip.

14. The package structure as claimed in claim 13, wherein the farther the second bump is from the center of the chip, the larger the indentation of the second bump is.

15. The package structure as claimed in claim 14, wherein the first portion of the second bump is closer to the center of the chip than the second portion is.

16. The package structure as claimed in claim 9, further comprising:
an underfill filled up an area between the chip and substrate.
